(19) United States
(12) Patent Application Publication
(10) Pub. No.: US 2022/0352467 A1
(43) Pub. Date: Nov. 3, 2022

(54) OVJP SYSTEM AND SUBLIMATION SOURCE

(71) Applicant: Universal Display Corporation, Ewing, NJ (US)

(72) Inventors: William E. QUINN, Whitehouse Station, NJ (US); Craig Anthony OUTTEN, Rydal, PA (US); Gregory MCGRAW, Yardley, PA (US); Matthew KING, Moorestown, NJ (US); Xin XU, Plainsboro, NJ (US)

(21) Appl. No.: 17/729,465

(22) Filed: Apr. 26, 2022

Related U.S. Application Data
(60) Provisional application No. 63/181,019, filed on Apr. 28, 2021.

(51) Int. Cl. H01L 51/00; C23C 14/12; C23C 14/22; C23C 16/44

(52) U.S. Cl. CPC H01L 51/0008; H01L 51/0004; C23C 14/12; C23C 14/228; C23C 16/4412

(57) ABSTRACT

Organic vapor jet printing (OVJP) devices and techniques are provided that use a solid materials sublimation source to provide material for deposition on a substrate. Carrier gas from a carrier gas source entrains vapor from the solid material within each sublimation source for transport to a print head within a deposition chamber. The sublimation source includes a sufficiently long internal flow path to achieve an acceptable level of material saturation of the carrier gas.

### CROSS-REFERENCE TO RELATED APPLICATIONS

This application claims the priority benefit of U.S. Patent Application Ser. No. 63/181,019, filed Apr. 28, 2021, the entire contents of which are incorporated herein by reference.

### FIELD

The present invention relates to devices and techniques for fabricating organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, an organic vapor jet printing (OVJP) deposition system includes a solid material sublimation source; a print head; a substrate holder configured to hold a substrate having a maximum length and a maximum width; and one or more gas transit lines connecting an exit channel of the solid material sublimation source to the print head; where a gas flow path between the solid material sublimation source and the print head through the one or more gas transit lines is not more than one half of the largest of the maximum length and the maximum width. The internal gas flow path within the solid material sublimation source may be at least 15 cm, 30 cm, or more. The gas flow path between the sublimation source and the print head through the one or more gas transit lines may be not more than one quarter of the largest of the maximum length and the maximum width. The system also may include one or more high-vacuum-compatible heaters disposed to provide thermal control of the solid material sublimation source. The solid material sublimation source may be disposed within a common deposition chamber with the print head.

A solid material sublimation source as disclosed herein may include a plurality of rectangular chambers, each of which includes a gas input channel at a first end of the chamber; a gas exit channel at a second end of the chamber, the second end being across a long axis of the chamber from the first end; and quick-connect fittings at the gas input channel and gas exit channel; where each of the plurality of rectangular channels is connectable via the quick-connect fittings to any of the other of the plurality of rectangular channels and to a gas input and a gas exit of the solid material sublimation source. The rectangular chambers may be configurable, via the quick-connect fittings, to receive carrier gas in series and in parallel configurations. Each chamber may include one or more heaters configured to heat the each chamber independently of each other chamber of the plurality of chambers.

A solid material sublimation source as disclosed herein may include one or more material trays, each of which includes a gas input channel; a gas exit channel; and a baffle disposed between the plurality of gas input channels and the plurality of gas exit channels and extending from a central portion of the material tray to an outer edge of the material tray; where the baffle causes carrier gas entering via the plurality of gas input channels to travel around the baffle before reaching the plurality of exit gas channels. Each baffle may extend from the floor of the material tray to the ceiling of the material tray, or at least 95% of the way to the ceiling of the material tray. Each material tray may be circular, in which case the baffle may extend across a complete radius of the associated material tray. The material tray may include a plurality of gas input channels and/or a plurality of gas exit channels.

A solid material sublimation source as disclosed herein may include vertical source container having a plurality of chambers, each of which includes a gas input channel; a gas exit channel; an upper portion and a lower portion separated from the upper portion by a porous divider and configured to hold a solid material source; and one or more baffles; where the one or more baffles are configured to direct gas sequentially through each of the plurality of chambers in alternating directions. A final chamber of the plurality of chambers may include a fine particle filter. The source may include 4 chambers such that the gas input channel of a first chamber of the plurality of chambers is configured to receive gas from a source external to the sublimation source; the gas exit channel of the first chamber is the gas input channel of a second chamber of the plurality of chambers; the gas exit channel of the second chamber is the gas input channel of a third chamber of the plurality of chambers; the gas exit channel of the third chamber is the gas input channel of a fourth chamber of the plurality of chambers; and the gas exit channel of the chamber is configured to direct gas out of the sublimation source. The source further may include a heating jacket disposed outside of and at least partially around the vertical source container. The solid source material may be disposed in the lower portion of each of the plurality of chambers.

### BRIEF DESCRIPTION OF THE DRAWINGS

FIG. 1 shows an organic light emitting device.

FIG. 2 shows an inverted organic light emitting device that does not have a separate electron transport layer.

FIGS. 3A-3B show examples of conventional liquid and solid material sources.

FIG. 3C shows an example of an alternate solid material source as used in semiconductor fabrication processes.

FIG. 4 shows a schematic view of an example OVJP system as disclosed herein.

FIG. 5 shows an example of an OVJP sublimation source as disclosed herein.

FIGS. 6A, 6B, 6C, 6D, and 6E show side and top views of example of an OVJP sublimation source as disclosed herein.

FIGS. 7A and 7B show end and side schematic views of an example of an OVJP sublimation source as disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

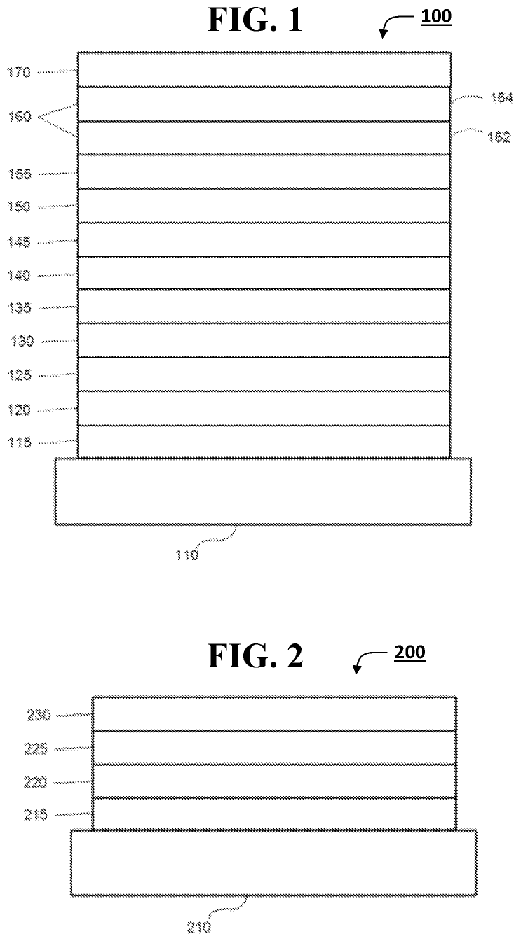

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light, which may be altered by another layer such as a color filter or other color altering layer that does not itself emit an initial light within the device, but may re-emit altered light of a different spectra content based upon initial light emitted by the emissive layer.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for interventing layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, Organic Vapor Jet Printing (OVJP) systems and techniques may be used to print fine lines of organic material, for example on a display backplane, without the use of fine metal shadow masks or liquid solvents, to provide various layers or components of OLEDs and similar devices. In contrast, conventional techniques used to fabricate mobile and laptop displays and similar devices typically use evaporation sources and fine metal masks to pattern the deposition. Fine metal masks are not suitable for use in manufacturing large area displays because the masks cannot be stretched with sufficient force to prevent sagging. Ink jet printing is a potential patterning technique for OLED displays and related devices, but the use of solvents to make the inks seriously degrades the performance of the light emitting devices. OVJP may be used to reduce or eliminate these issues by printing lines of pixel-width size and resolution without the use of fine metal masks and uses state of the art OLED materials without dissolving them in solvent.

In OVJP, OLED materials are heated in an enclosed container to an elevated sublimation temperature and transported to a print head through heated gas lines using an inert carrier gas. The print head contains jetting apertures with a spacing that corresponds to the pixel spacing of the display. Apertures are formed in silicon wafers using standard MEMS fabrication techniques and functional OVJP die are cut from the wafer, with the apertures along one edge of the die. The aperture edge of the die is held above a moving display backplane and lines corresponding to the pixels are printed on the backplane.

The sealed container that holds the organic material is called a solid material source or solid material sublimation source. At room temperature, the vapor pressure of the organic material is negligible. When heated, the vapor pressure increases and the material begins to sublimate. To transport the sublimated organic material to the print head, an inert carrier gas such as helium, argon or nitrogen is used. The carrier gas flows through the sealed container, through heated gas lines to the print head where the material is subsequently condensed on the cool backplane substrate. The amount of material that is transported to the print head is a function of the temperature of the sublimation source, carrier gas flow and design of the sublimation source.

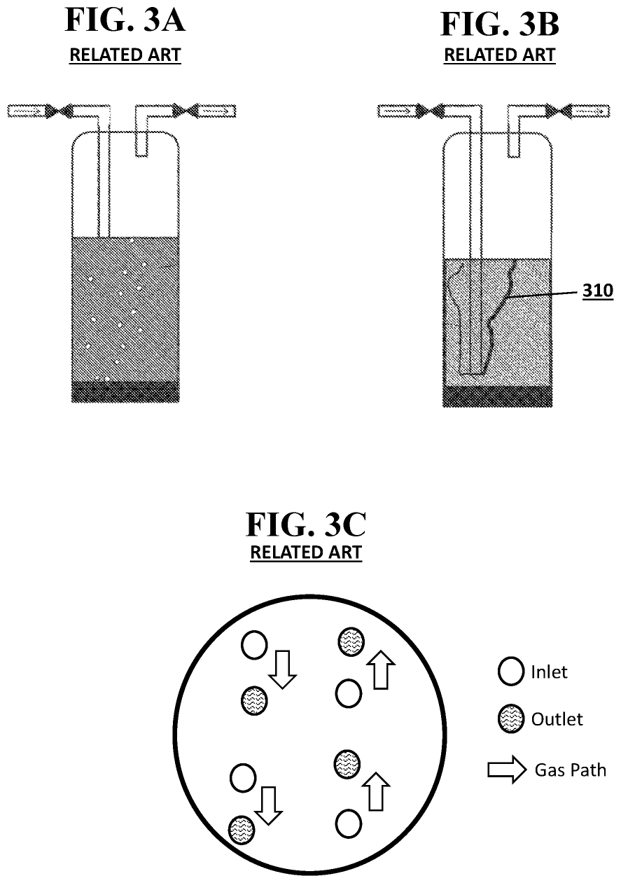

Most OLED materials are solids at their deposition temperature (i.e., the temperature to which they are heated to effect deposition) and have appreciable vapor pressure without melting or liquifying. A saturated vapor may be readily formed from a liquid source, for example by using a bubbler-type ampule as shown in FIG. 3A. The liquid is placed in a container with a long dip tube that extends from the top of the container to near the bottom and an exit tube at the top of the container. Carrier gas is flowed through the dip tube and forms small bubbles as the gas exits the tube into the liquid. The gas bubbles become saturated with liquid vapor as they rise through the liquid and the saturated vapor flows from the container through the exit tube. Liquid bubblers provide a stable saturation level of material in carrier gas as the small bubbles have a very large surface to volume ratio and saturate quickly.

Similar devices typically cannot be used to obtain a stable vapor concentration for solid materials. If a liquid bubbler or similar device is loaded with solid material, for example as shown in FIG. 3B, the initial vapor concentration is high. However, after some time of operation, channels typically develop in the solid, for example as shown at 310, which minimizes the contact area between the carrier gas and solid material. The small contact area limits the extent to which the vapor becomes saturated, and control of the material flux from the ampule is not predictable over time.

One approach to addressing these issues is to use multiple trays that hold the solid source material. For example, U.S. Pat. No. 6,921,062 describes a source for use in semiconductor manufacturing that uses a number of trays through which a gas flows sequentially. Each tray is filled with solid material and contains a number of input and exit tubes for the carrier gas as shown in FIG. 3C. These tubes are close to each other and the path length of the gas over the source material from input to exit tube is short. Although it may avoid the issues with adapting a liquid arrangement to use a solid source material as shown in FIG. 3B, in general this type of source is unsuitable for use with OVJP processes and materials. The internal gas path length is relatively short for each pair of input/outlet apertures, so the amount of material provided by each tray and each pair of apertures may be relatively low compared to other source arrangements. Such a source may have other drawbacks, such as being unsuitable for use with light or fine powders or requiring too high a temperature for long-term OVJP use. Further, a high rate or volume of carrier gas flow likely would cause undesirable turbulence and particles in the trays. The general arrangement also is not conducive to long-term use as each tray needs to be disassembled to clean and refill, which must be done separately for each tray.

Embodiments disclosed herein provide OVJP systems and source material containers (or “sublimation sources”) that provide for improved performance of OVJP techniques. The devices, systems, and techniques disclosed herein may be particularly suited to OVJP in contrast to other deposition techniques such as atomic layer deposition (ALD), chemical vapor deposition (CVD), and the like. One difference between OVJP and other techniques is the temperatures at which each part of the deposition system operates in order to maintain desired pressures, material state, gas or other material flow, and the like. For example, OVJP typically uses temperatures of 200-500 C for source crucibles and the gas run lines between source material containers and the print head, and temperatures of 0-80 C for the substrate on which material is to be deposited. This is significantly different from other deposition techniques, which typically use heated substrates and different combinations of temperatures and pressure variations throughout the deposition system. For example, ALD and various CVD processes typically use gas run line temperatures of 25-150 C. At these temperatures, OVJP materials likely would exhibit a large degree of condensation within the gas lines. ALD and variations of CVD techniques also use much higher substrate temperatures, typically 25-800 C for ALD and 600-1200 for conventional CVD processes. Some CVD techniques may use slightly lower temperature, such as plasma-enhanced CVD (PECVD) which can operate in the 200-400 C range when depositing oxides, nitrides, and other materials for semiconductor, optoelectronic, or similar uses, or 25-400 C for non-semiconductor applications. Low-pressure CVD (LPCVD) typically operates in the 400-900 C range for semiconductor and optoelectronic devices. Even where CVD-based techniques may use substrate temperatures that may overlap acceptable ranges for OVJP processes, the devices and systems would not be suitable for OVJP use due to the likelihood of the deposition system transmitting heat to the substrate, which would damage organic materials on the substrate and/or prevent proper deposition of organic materials entrained in the carrier gas. Accordingly, as used herein, an “OVJP deposition system” or “OVJP system” or other OVJP component excludes devices and systems designed and intended for use with ALD, CVD, or similar non-OVJP processes. Furthermore, as previously described, an OVJP system typically operates at different temperature ranges and combinations of temperature ranges for the gas transfer lines and substrate than are used in other processes. Accordingly, an OVJP system as disclosed herein may be distinguished from other depositions systems in that it is both configured to, and capable of, operating in OVJP temperature ranges as disclosed without damaging the system, the substrate, or the materials being deposited on the substrate.

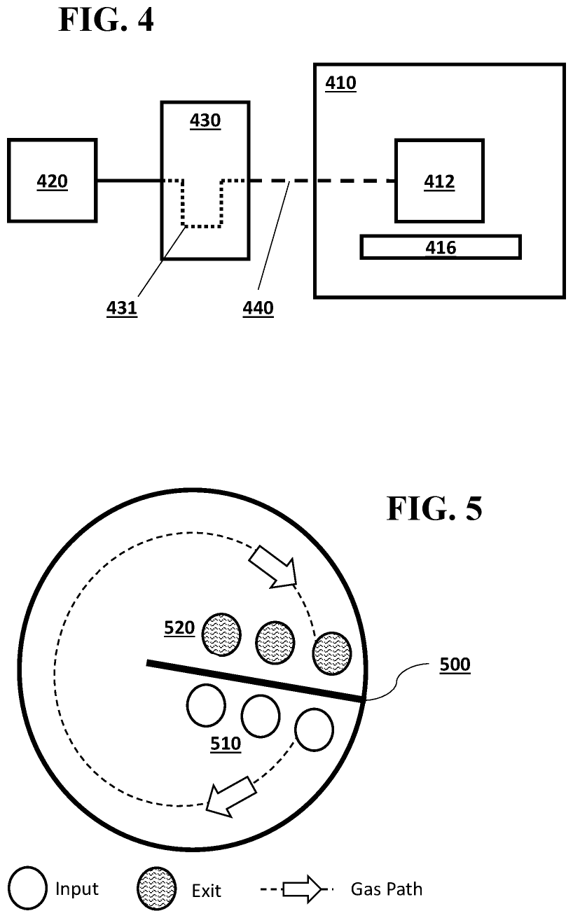

FIG. 4 shows an example OVJP system according to embodiments disclosed herein. The system includes a deposition chamber 410 with controllable pressure, within which one or more print heads 412 is used to deposit material on a substrate arranged on a substrate holder 416. The substrate holder generally will be sufficiently large to accommodate any size substrate up to some maximum edge dimension (length or width) and any thickness suitable for OVJP applications. The substrate may be, for example, glass or plastic, and may be flexible, transparent, semi-transparent, rollable, foldable, or combinations thereof or, more generally, any form of substrate suitable for use with OVJP processes. A source of carrier gas 420 is used to provide carrier gas through one or more sublimation sources 430, which typically are heated to cause vaporized material to be entrained in the carrier gas as it passes through the sublimation source. In some embodiments, the carrier gas source 420, some or all of any solid sublimation sources 430 used in the system, or any combination thereof may be located within the deposition chamber or external to the deposition chamber. One or more heaters may be used to provide thermal control of the sublimation source 430, which may be disposed around and/or within the sublimation source or any internal chambers of the source. In some cases the heaters may be high-vacuum compatible, for example to allow for the sublimation source to be placed within the deposition chamber 410.

The carrier gas may flow through gas transit lines 440 between an exit of the solid sublimation source 430 and an input of the print head 412, which may be referred to herein as an “external” gas flow path or a gas flow path between the solid sublimation source and the print head. Inside the solid sublimation source, the gas may travel along an “internal” gas flow path 431 that is entirely contained within the solid sublimation source. As used herein, the gas flow path refers to the actual path followed by the carrier gas as it moves through the relevant part of the OVJP system, as opposed to a straight-line distance between the beginning and end of the associated container and/or gas lines. Generally, it is desirable for the internal gas flow path 431 to be relatively long to allow for a higher level of saturation of the carrier gas with material to be deposited by the print head 412. Conversely, generally it is desirable for the external flow path 440 between the solid sublimation source 430 and the print head 412 to be relatively short to prevent condensation within the gas transit lines and to reduce the amount of heating required to avoid such condensation. For example, for some common substrate sizes and organic materials, it may be preferred for the external flow path 440 to be not more than 30 cm and for the internal gas flow path to be at least 15 cm, more preferably at least 30 cm.

More generally, larger substrates may require the external flow path through the gas transit lines 440 to be larger. Accordingly, it also may be desirable for the external flow path 440 to be not more than one half, or more preferably not more than one quarter of the maximum substrate dimension, i.e., not more than 50% or 25% of the largest edge dimension of the substrate (length or width). For example, embodiments disclosed herein may use the following maximum external flow paths (EFPs) in conjunction with common substrate dimensions (or half the listed maximum for flow paths one-quarter of the maximum substrate edge dimension):

| Example | Length | Width | EFP Max |
|---|---|---|---|
| Substrate | (mm) | (mm) | (mm) |
| GEN 1 | 300 | 400 | 200 |
| GEN 2 | 370 | 470 | 235 |
| GEN 3 | 550 | 650 | 325 |
| GEN 3.5 | 600 | 720 | 360 |
| GEN 4 | 680 | 880 | 440 |
| GEN 4.5 | 730 | 920 | 460 |
| GEN 5 | 1100 | 1250-1300 | 625-650 |
| GEN 6 | 1500 | 1800-1850 | 900-925 |
| GEN 7 | 1870 | 2200 | 1100 |
| GEN 8 | 2160 | 2460 | 1230 |
| GEN 8.5 | 2200 | 2500 | 1250 |
| GEN 10 | 2880 | 3130 | 1565 |
| GEN 10.5 | 2940 | 3370 | 1685 |
| | 3000 | 3000 | 1500 |
| | 4000 | 3000 | 2000 |
| | 3000 | 4000 | 2000 |
| | 4000 | 4800 | 2400 |
| | 8000 | 8800 | 4400 |
| | 10,000 | 10,000 | 5000 |

To achieve the desired arrangement of solid sublimation sources, print head, and other components of an OVJP system as disclosed herein, any of several arrangements of solid sublimation sources may be used which provide for higher saturation of the carrier gas and generally more efficient use of the OVJP material to be deposited on the substrate, leading to improved performance relative to conventional OVJP systems and sublimation sources.

FIG. 5 shows an embodiment of a solid sublimation source as disclosed herein, which incorporates an improvement to an arrangement such as described in U.S. Pat. No. 6,921,062. In this example, the sublimation source includes one or more trays that may be filled with the material to be deposited by the OVJP system. Each tray may include one or more gas input channels and one or more gas exit channels. The gas input channel of a first tray may be connected to the carrier gas source, such as 420 in FIG. 4, and the gas exit channel of a final tray in the source may be connected to an external gas transfer line such as 440 in FIG. 4. Internally, the gas exit channel of an earlier tray may be connected to the gas input channel of a subsequent tray. Gas flows from the lowest tray sequentially to the top tray and then exits the container.

In each tray, the carrier gas flows into the tray from one or more inlet apertures 510, through the tray, and out of the tray via one or more outlets 520. A baffle 500 extending from the center or near the center of each tray to the edge wall of the tray, separating the input tubes 510 on one side of the baffle from the exit tubes 520 on the other. In this way, the carrier gas must travel over the circumferential length of the tray before reaching the exit. The baffle may extend from the floor of the material tray to the ceiling of the tray or essentially to the ceiling of the tray, such that no carrier gas or only a de minimis amount of carrier gas may travel over the baffle to move from the gas input(s) to the exit channel(s). Preferably, the baffle extends is at least 95%, preferably 96%, more preferably 97%, 98%, or 99% of the height of the tray. The baffle may extend from the center of the tray to an outer edge, i.e., along a complete radius of the tray. Where a non-circular tray is used, the baffle may extend from the center or a centroid of the tray to a farthest wall of the tray, a closest wall of the tray, or any point in between. For example, if an ellipsoidal tray is used, the baffle may extend along a complete minor radius or a complete major radius of the tray. Among other effects, this increases the contact time and surface area exposed to carrier gas, thereby improving the saturation of the carrier gas and the system efficiency. The gas flow path for a tray as shown in FIG. 5 refers to the circumferential path from an input to an associated exit channel where multiple input and exit channels are used. In the case of a single input and single exit, the gas flow path refers to the circumferential distance between the centers of the two. Otherwise, the gas flow path may be determined as the average of all closest-fit circumferential paths between each input and each exit.

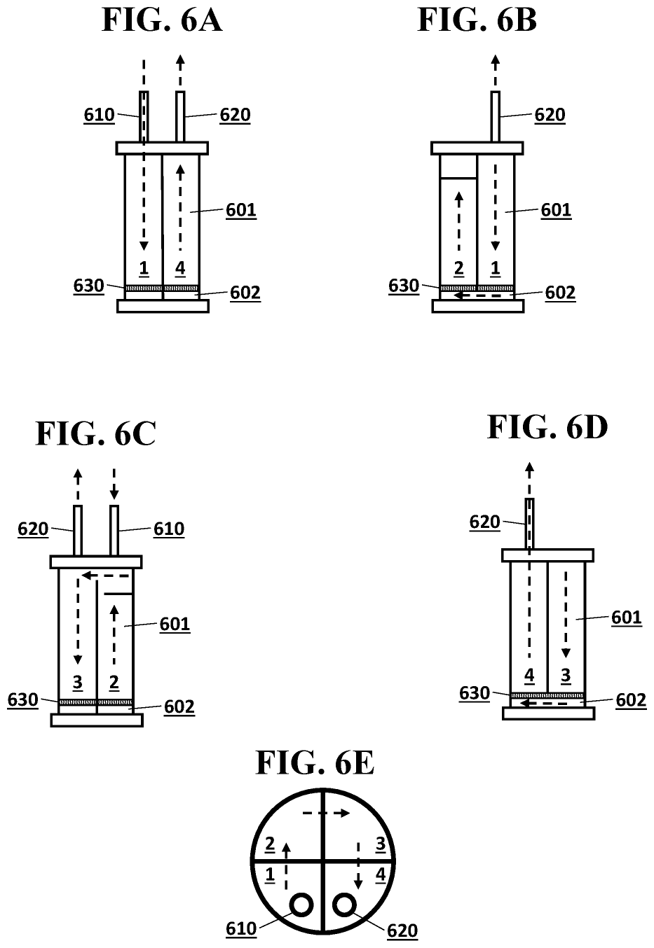

FIGS. 6A-6D show schematic side views of a vertical OVJP solid sublimation source as disclosed herein; FIG. 6E shows a top view of the same source. FIGS. 6A-6D show the source as viewed from each side, with the view rotating 90 degrees around the source between 6A and 6B, 6B and 6C, and 6C and 6D. Dashed arrows show the direction of gas flow through the chambers of the source. Each of the four chambers includes a gas input channel 610, a gas exit channel 620, and upper and lower portions 601, 602 separated by a porous divider 630 such as a screen, frit, or the like. The gas input channel of the first chamber may be connected to the source of carrier gas, and the gas exit channel of the final chamber may be connected to an external gas transfer line such as 440 in FIG. 4.

The bottom of each vertical chamber contains the solid material to be entrained in the carrier gas and provides a wide channel for carrier gas flow. The gas flows sequentially through chambers 1-4, with baffles in each chamber configured to alter the direction of flow from one chamber to the next. In the example shown in FIGS. 6A-6E, gas flow begins downward from the gas input in chamber 1, then upward in chamber 2, downward in chamber 3 and upward in chamber 4 to the final gas exit. A solid sublimation source as shown in FIGS. 6A-6E is advantageous due to the relatively long path length through the four chambers and the slow gas velocity caused by the porous divider increasing the area of carrier gas flow, which provides a gas flow with lower velocity than a small cross-section gas stream. The chambers may be heated, for example, via a heating jacket wrapped around the circumference of the source and on the top and bottom flanges. Such a design may be especially advantageous for pelletized or chunk-type material. In some embodiments, the final chamber may include or may itself be used as a particle trap to allow for use with fine powders. For example, the final chamber may include a fine particle filter or similar component to trap material for removal or re-use. A sublimation source as shown in FIGS. 6A-6E may include four chambers as shown, or any other number of chambers.

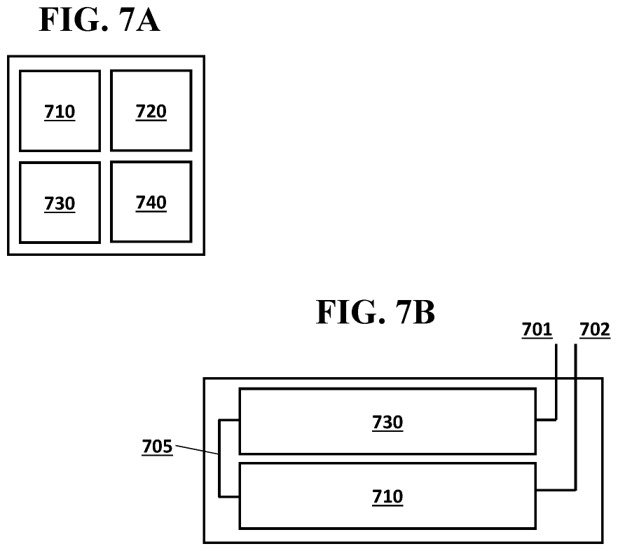

FIGS. 7A and 7B show end and side views, respectively, of another example of an OVJP solid sublimation source as disclosed herein. The source includes any number of chambers 710, 720, 730, 740, which may be arranged within the source chamber. Each chamber may be provided already filled with material to be deposited via the OVJP system. The chambers may have quick-connect fittings on the ends to allow them to be easily and individually placed in or removed from the sublimation source. Chambers may be connected to input and exit fittings 701, 702, respectively, and interior gas lines 705 may be used to connect the interior chambers so that they can be used in series, in parallel, individually, or any combination thereof. Although four chambers are shown for purposes of illustration, more generally any number of chambers may be used. The chambers may be rectangular to allow for efficient packing within the solid sublimation source. The sublimation source shown in FIGS. 7A-7B may include one or more heaters that may be operated in tandem or individually, to allow for control of the overall temperature of the sublimation source and/or individual control of each chamber.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An organic vapor jet printing (OVJP) deposition system comprising:
a solid material sublimation source;
a print head;
a substrate holder configured to hold a substrate having a maximum length and a maximum width; and
one or more gas transit lines connecting an exit channel of the solid material sublimation source to the print head;
wherein a gas flow path between the solid material sublimation source and the print head through the one or more gas transit lines is not more than one half of the largest of the maximum length and the maximum width.

2. The deposition system of claim 1, wherein an internal gas flow path within the solid material sublimation source is not less than 15 cm.

3. The deposition system of claim 1, wherein the a gas flow path between the sublimation source and the print head through the one or more gas transit lines is not more than one quarter of the largest of the maximum length and the maximum width.

4. (canceled)

5. (canceled)

6. (canceled)

7. The deposition system of claim 1, wherein the solid material sublimation source comprises:
a plurality of rectangular chambers, each chamber comprising:
a gas input channel at a first end of the chamber;
a gas exit channel at a second end of the chamber, the second end being across a long axis of the chamber from the first end;
quick-connect fittings at the gas input channel and gas exit channel;
wherein each of the plurality of rectangular channels is connectable via the quick-connect fittings to any of the other of the plurality of rectangular channels and to a gas input and a gas exit of the solid material sublimation source.

8. (canceled)

9. (canceled)

10. The deposition system of claim 1, wherein the solid material sublimation source comprises:
one or more material trays, each material tray of the one or more material trays comprising:
a gas input channel;
a gas exit channel; and
a baffle disposed between the plurality of gas input channels and the plurality of gas exit channels and extending from a central portion of the material tray to an outer edge of the material tray;
wherein the baffle causes carrier gas entering via the plurality of gas input channels to travel around the baffle before reaching the plurality of exit gas channels.

11. The deposition system of claim 10, wherein the one or more material trays comprises a plurality of material trays.

12. The deposition system of claim 10, wherein each baffle extends from the floor of the material tray to the ceiling of the material tray.

13. The deposition system of claim 10, wherein each material tray is circular and each baffle extends across a complete radius of the associated material tray.

14. (canceled)

15. (canceled)

16. The deposition system of claim 1, wherein the solid material sublimation source comprises:
a vertical source container comprising:
a plurality of chambers, each chamber of the plurality of chambers comprising:
a gas input channel;
a gas exit channel;
an upper portion;
a lower portion separated from the upper portion by a porous divider and configured to hold a solid material source; and
one or more baffles; and
wherein the one or more baffles are configured to direct gas sequentially through each of the plurality of chambers in alternating directions.

17. The deposition system of claim 16, wherein a final chamber of the plurality of chambers comprises a fine particle filter.

18. The deposition system of claim 16, wherein:
the plurality of chambers comprises 4 chambers;
the gas input channel of a first chamber of the plurality of chambers is configured to receive gas from a source external to the sublimation source;
the gas exit channel of the first chamber is the gas input channel of a second chamber of the plurality of chambers;
the gas exit channel of the second chamber is the gas input channel of a third chamber of the plurality of chambers;
the gas exit channel of the third chamber is the gas input channel of a fourth chamber of the plurality of chambers; and
the gas exit channel of the chamber is configured to direct gas out of the sublimation source.

19. (canceled)

20. (canceled)

21. A solid material sublimation source for a vapor deposition system, the solid material sublimation source comprising:
one or more material trays, each material tray of the one or more material trays comprising:
a gas input channel;
a gas exit channel; and
a baffle disposed between the plurality of gas input channels and the plurality of gas exit channels and extending from a central portion of the material tray to an outer edge of the material tray;
wherein the baffle causes carrier gas entering via the plurality of gas input channels to travel around the baffle before reaching the plurality of exit gas channels.

22. The sublimation source of claim 21, wherein the one or more material trays comprises a plurality of material trays.

23. The sublimation source of claim 21, wherein each baffle extends from the floor of the material tray to the ceiling of the material tray.

24. The sublimation source of claim 21, wherein each material tray is circular and each baffle extends across a complete radius of the associated material tray.

25. The sublimation source of claim 21, wherein each material tray comprises a plurality of gas input channels and/or a plurality of gas exit channels.

26. (canceled)

27. A solid material sublimation source for a vapor deposition system, the solid material sublimation source comprising:
a vertical source container comprising:
a plurality of chambers, each chamber of the plurality of chambers comprising:
a gas input channel;
a gas exit channel;
an upper portion;
a lower portion separated from the upper portion by a porous divider and configured to hold a solid material source; and
one or more baffles; and
wherein the one or more baffles are configured to direct gas sequentially through each of the plurality of chambers in alternating directions.

28. The sublimation source of claim 27, wherein a final chamber of the plurality of chambers comprises a fine particle filter.

29. The sublimation source of claim 27, wherein:
the plurality of chambers comprises 4 chambers;
the gas input channel of a first chamber of the plurality of chambers is configured to receive gas from a source external to the sublimation source;
the gas exit channel of the first chamber is the gas input channel of a second chamber of the plurality of chambers;
the gas exit channel of the second chamber is the gas input channel of a third chamber of the plurality of chambers;
the gas exit channel of the third chamber is the gas input channel of a fourth chamber of the plurality of chambers; and
the gas exit channel of the fourth chamber is configured to direct gas out of the sublimation source.

30. (canceled)

31. The sublimation source of claim 27, further comprising a solid source material disposed in the lower portion of each of the plurality of chambers.
